(19) United States
(12) Patent Application Publication
(10) Pub. No.: US 2016/0013299 A1
(43) Pub. Date: Jan. 14, 2016

(54) SEMICONDUCTOR DEVICE, DRIVE DEVICE FOR SEMICONDUCTOR CIRCUIT, AND POWER CONVERSION DEVICE

(71) Applicant: HITACHI, LTD., Chiyoda-ku,Tokyo (JP)

(72) Inventors: Takayuki HASHIMOTO, Tokyo (JP); Mutsuhiro MORI, Tokyo (JP)

(73) Assignee: Hitachi, Ltd., Chiyoda-ku, Tokyo (JP)

(21) Appl. No.: 14/770,443

(22) PCT Filed: Feb. 25, 2013
(86) PCT No.: PCT/JP2013/054660

§ 371 Date: Aug. 25, 2015

(51) Int. Cl. H01L 29/739; H01L 29/36; H02M 7/53; H01L 29/423

(52) U.S. Cl. CPC H01L 29/7391; H01L 29/4236; H01L 29/36; H01L 29/7393; H02M 7/53

(57) ABSTRACT

A semiconductor device according to the present invention includes: a first semiconductor layer of a first conductivity type; a second semiconductor layer of the first conductivity type, which is adjacent to the first semiconductor layer and has an impurity concentration lower than the first semiconductor layer; a third semiconductor layer adjacent to the second semiconductor layer; a first electrode electrically coupled to the third semiconductor layer; a second electrode electrically coupled to the first semiconductor layer; and an insulated gate provided over the surface of the third semiconductor layer. Then, an end portion of the insulated gate is located at a position distant from the junction part between the second semiconductor layer and the third semiconductor layer within the surface of the third semiconductor layer.

### TECHNICAL FIELD

The present invention relates to a semiconductor device, a drive device for a semiconductor circuit using the semiconductor device, and a power conversion device. More particularly, the present invention relates to a semiconductor device suitable for wide range of applications, from small power devices such as air conditioners and microwaves to large power devices such as inverters for railroad and steel plants, and relates to a drive device for a semiconductor circuit as well as a power conversion device.

### BACKGROUND ART

Many inverters and converters are used in recent power saving and new energy power conversion devices, and it is necessary to promote the use of such power conversion devices in order to achieve low carbon society. FIG. 14 shows an example of an inverter capable of achieving energy savings by variably controlling the speed of a motor 950. An electric energy from a DC power supply 960 is changed to AC of a desired frequency by using an IGBT (Insulated Gate Bipolar Transistor) 700, which is a kind of power semiconductor, to variably control the speed of rotation of the motor 950. The motor 950 is a three-phase motor with inputs of U-phase 910, V-phase 911, and W-phase 912. The input power of the U-phase 910 is supplied by turning on a gate circuit 800 of the IGBT 700 (hereinafter referred to as the upper arm IGBT) in which a collector is coupled to a power supply terminal 900 on the plus side. The input power of the U-phase 910 can be stopped by turning off the gate circuit 800. By repeating this operation, the AC power of desired frequency can be supplied to the motor 950.

A flywheel diode 600 is connected in reverse parallel to the IGBT 700. For example, when the upper arm IGBT 700 is turned off, the flywheel diode 600 releases the energy accumulated in the coil of the motor 950 by turning the current flowing through the IGBT 700 to the flywheel diode 600 that is connected in reverse parallel to the IGBT 700 (hereinafter referred to as the lower arm IGBT) in which an emitter is coupled to a power supply terminal 901 on the minus side. When the upper arm IGBT 700 is turned on again, the lower arm flywheel diode 600 is brought into a nonconductive state, so that the power is supplied to the motor 950 through the upper arm IGBT 700. The IGBT 700 and the flywheel diode 600 generate conduction losses during conduction and generate switching during switching. For this reason, it is necessary to reduce the conduction losses of the IGBT 700 and the flywheel diode 600 as well as their switching losses in order to reduce the size and increase the efficiency of the inverter.

The technology described in Patent Literature 1 is known as a technology for reducing the conduction loss and recovery loss of the flywheel diode. The diode described in Patent Literature 1 includes an embedded insulated gate that is placed within a trench groove. During conduction, a negative voltage is applied to the insulated gate to form a hole accumulation layer in order to reduce the forward voltage. On the other hand, during recovery, the gate voltage is set to zero to prevent hole injection from the anode in order to reduce the recovery loss. In this way, it is possible to control the efficiency of the hole injection from the anode, so that it is possible to improve the trade-off between the forward voltage and the recovery loss.

### CITATION LIST

### Patent Literature

Patent Literature 1: Japanese Patent Application Laid-Open No. HEI 10(1998)-163469 (FIG. 1)

### SUMMARY OF INVENTION

### Technical Problem

The present inventors have found that the conventional problem described above has the following problem.

According to the studies made by the inventors, it is found that the diode according to the prior art can further prevent the hole injection by applying a positive voltage to the gate during recovery. However, it is also found that it is difficult to maintain the reverse breakdown voltage when the positive voltage is applied to the gate.

The present invention has been made in view of the above problem, and an object of the present invention is to reduce the recover loss without reducing the breakdown voltage of the diode.

### Solution to Problem

In order to solve the above problem, a semiconductor device according to the present invention includes: a first semiconductor layer of a first conductivity type; a second semiconductor layer of the first conductivity type, which is adjacent to the first semiconductor layer and has an impurity concentration lower than the first semiconductor layer; a third semiconductor layer of a second conductivity type adjacent to the second semiconductor layer; a first electrode electrically coupled to the second semiconductor layer; a second electrode brought into contact with the first semiconductor layer; and an insulated gate provided over the surface of the third semiconductor layer. Further, in the semiconductor device, an end portion of the insulated gate is located at a position distant from the junction part between the second semiconductor layer and the third semiconductor layer, within the surface of the third semiconductor layer.

Here, the first semiconductor layer, the second semiconductor layer, the third semiconductor layer, the first electrode, and the second electrode correspond to, for example, an n+ type cathode layer, an n− type drift layer, a p− type channel layer, an anode electrode, and a cathode electrode, respectively, which will be described in the following embodiments.

### Advantageous Effects of Invention

According to the present invention, it is possible to provide a diode with low loss and low noise, so that it is possible to increase the efficiency and reduce the size of a semiconductor device and a power conversion device.

### BRIEF DESCRIPTION OF DRAWINGS

FIG. 1 is a cross-sectional view of a semiconductor device which is a first embodiment of the present invention.

FIG. 2 shows a hole density distribution between anode and cathode.

FIG. 3 shows the output characteristics.

FIG. 4 shows the relationship between the forward voltage and the recovery loss.

FIG. 5 shows recovery waveforms.

FIG. 6 shows the relationship between the sheet carrier of the p− type channel layer and the forward voltage.

FIG. 7 shows an electric field distribution.

FIG. 8 shows a gate drive sequence during recovery.

FIG. 9 shows a waveform of the forward voltage.

FIG. 10 is a cross-sectional view of a semiconductor device which is a second embodiment of the present invention.

FIG. 11 is a cross-sectional view of a semiconductor device which is a third embodiment of the present invention.

FIG. 12 is a cross-sectional view of a semiconductor device which is a fourth embodiment of the present invention.

FIG. 13 is a cross-sectional view of a semiconductor device which is a fifth embodiment of the present invention.

FIG. 14 is a circuit block diagram for illustrating the prior art, as well as a power conversion device which is a ninth embodiment of the present invention.

FIG. 15 is a circuit diagram of a drive device which is a sixth embodiment of the present invention.

FIG. 16 is a circuit diagram of a drive device which is a seventh embodiment of the present invention.

FIG. 17 is a circuit diagram of a drive device which is an eighth embodiment of the present invention.

FIG. 18 is a cross-sectional view of a semiconductor device which is a variation of the first embodiment.

FIG. 19 is a cross-sectional view which is another variation of the first embodiment.

FIG. 20 is a cross-sectional view of a semiconductor device which is still another variation of the first embodiment.

### DESCRIPTION OF EMBODIMENTS

Hereinafter, the embodiments of the present invention will be described with reference to the accompanying drawings. Note that the symbols of n−, n, and n+ in the figures snow that the semiconductor layers are n type, showing that the impurity concentration is relatively high in this order. Further, the symbols of p−, p and p+ show that the semiconductor layers are p type, showing that the impurity concentration is relatively high in this order.

### First Embodiment

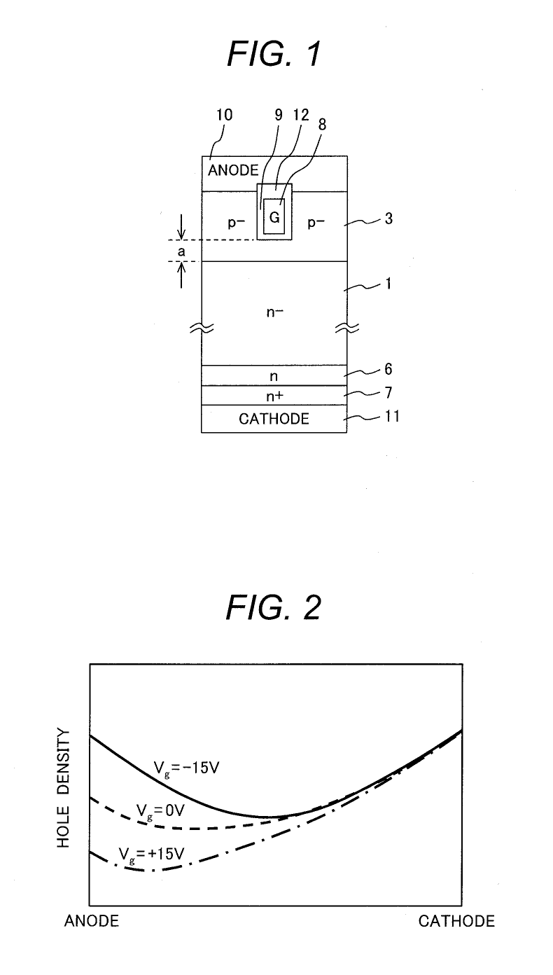

FIG. 1 is a cross-sectional view of an insulated gate type vertical semiconductor device which is a first embodiment of the present invention.

The present embodiment is a trench gate control diode including: an n− type drift layer 1; a p− type channel layer 3 vertically adjacent to the n− type drift layer; an n type buffer layer 6 vertically adjacent to the n− type drift layer 1 on the opposite side of the p− type channel layer 3; and n+ type cathode layer 7 vertically adjacent to the n type buffer layer 6 on the opposite side of the n− type drift layer 1. Further, the present embodiment also includes an insulated gate, which is a trench gate type, having a gate electrode 8 provided over the surface of the p− type channel layer 3 through a gate insulating film 9, within the so-called trench groove. The bottom portion of the trench groove is located within the p− type channel layer 3, and is separated from the pn junction between the p− type channel layer 3 and the n− type drift layer 1. In other words, the lower end portion of the trench type insulated gate, which is the bottom portion of the trench groove, is located within the surface of the p− type channel layer in the side wall of the trench groove, and at the same time, is located at a position distant from the junction part between the n− type drift layer 1 and the p− type channel layer 3. An anode electrode 10 is electrically coupled to the p− type channel layer 3 by an ohmic contact or a Schottky contact. Further, a cathode electrode 11 is brought into ohmic contact with the n+ type cathode layer 7, and thus is electrically coupled to the n type buffer layer 6 and the n− type drift layer 1.

Next the operation of the present embodiment will be described.

During conduction, a negative voltage is applied to the gate electrode 8 with respect to the anode electrode 10, so that a p type accumulation layer is formed at the interface between the p− type channel layer 3 and the gate insulating film 9. A lot of holes are injected into the n− type drift layer 1 through the p type accumulation layer. As a result, the forward voltage (Vf) is reduced and the conduction loss is reduced.

On the other hand, during recovery, when the same voltage as the anode electrode 10 or a positive voltage with respect to the anode electrode 10 is applied to the gate electrode 8, the hole injection from the p− type channel layer 3 to the n− type drift layer 1 is prevented. As a result, the recovery loss is reduced. According to the studies of the present inventors, it is found that the recovery loss can be reduced more when the gate electrode 8 has a positive voltage rather than 0 volt. This is because the electrons injected from the cathode through the n type inversion layer, which is formed at the interface between the p− type channel layer 3 and the gate insulating film 9, are discharged to the anode electrode 10 and thus the hole injection from the p− type channel layer 3 is prevented.

In the present embodiment, the pn junction between the p− type channel layer 3 and the n− type drift layer 1 is separate from the bottom portion of the trench groove by a distance a. In this way, the depletion layer does not reach the n type inversion layer even if a positive voltage is applied to the gate electrode 8, so that it is possible to reduce the recovery loss without reducing the breakdown voltage.

FIG. 2 shows a hole density distribution between anode and cathode during conduction. When 0 volt (Vg=0 V in the figure) is applied to the gate electrode 8, the hole density on the anode side is reduced more as compared to the application of the negative voltage (Vg=−15 V in the figure). When the positive voltage (Vg=+15 V in the figure) is applied to the gate electrode 8, the hole density is further reduced. This is because the n type inversion layer is formed at the interface between the p− type channel layer 3 and the gate insulating film 9, and the electrons injected from the n+ type cathode layer 7 are discharged to the anode electrode 10 through the n type inversion layer, so that the hole injection from the p− type channel layer 3 is reduced. When the negative voltage (−15 V in the figure) is applied to the gate electrode 8, the current path through the n type inversion layer disappears and the p type accumulation layer is formed, so that the hole density on the anode side is increased.

Note that in the present embodiment, the n type inversion layer is formed in the p− type channel layer 3 by setting the gate voltage equal to or greater than the threshold value. However, the potential of the channel with respect to the electrons is reduced even when the gate voltage is set to a positive voltage lower than the threshold value, so that the electrons flow to the anode electrode through the path in which the potential is reduced. Thus, in this case also, the hole density is reduced on the anode side during conduction.

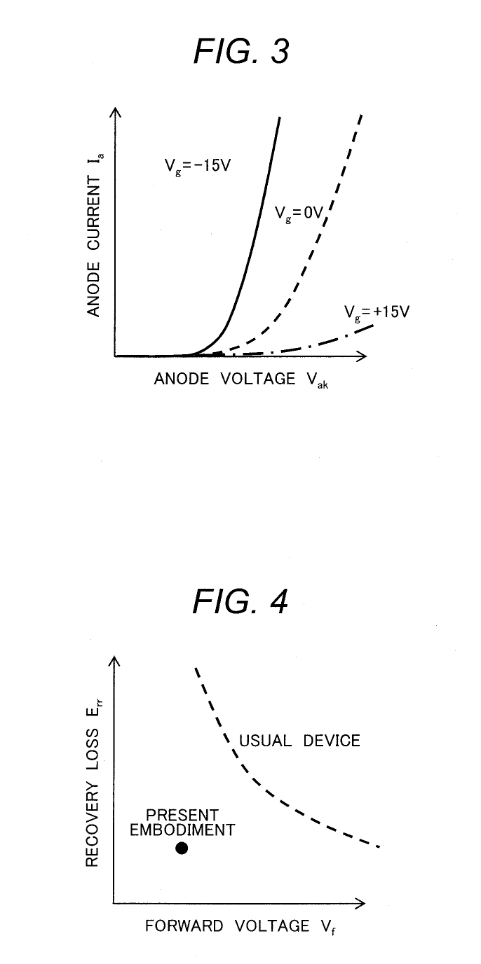

FIG. 3 shows the output characteristics when positive voltage, 0 volt, and negative voltage are applied to the gate electrode 8. When the negative voltage is applied to the gate electrode 8, the anode current is large and the forward voltage Vf is small because the hole density on the anode side is high as shown in FIG. 2. When 0 volt is applied to the gate electrode 8, the anode current is reduced and the forward voltage Vf is increased because the hole density on the anode side is reduced. When the positive voltage is applied to the gate electrode 8, the anode current is reduced and the forward voltage Vf is increased because the hole density on the anode side is further reduced. In other words, in the present embodiment, it is possible to practically switch between the diode whose forward voltage drop (Vf) is lower than the gate electrode 8, namely, the diode with high recovery loss, and the diode whose forward voltage drop (Vf) is higher than the gate electrode 8, namely, the diode with low recovery loss. In this way, both the conduction loss and the recovery loss, or the switching loss can be reduced.

FIG. 4 shows the relationship between the forward voltage (Vf) and the recovery loss (Err). The dashed line corresponds to a usual pin diode. In the present embodiment, it is possible to reduce both the forward voltage (Vf) and the recovery loss (Err) by dynamically controlling the gate voltage within one cycle of switching. As a result, improve the trade-off characteristics can be improved.

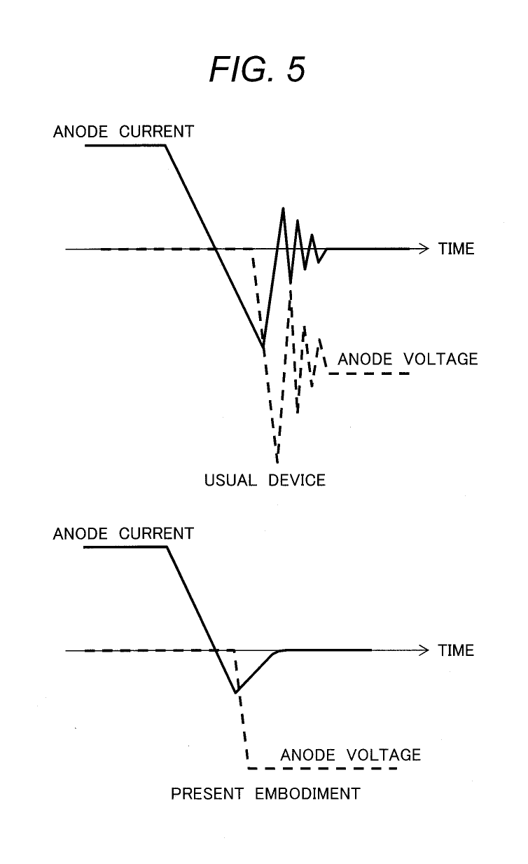

FIG. 5 shows the waveforms of the anode current and the anode voltage during recovery according to the present embodiment. The upper part shows the usual pin diode and the lower part shows the present embodiment. The forward voltage drop (Vf) is the same in the prior art and the present embodiment. In the usual pin diode, the peak value of the reverse anode current (reverse recovery current Irp) is large, so that the peak value of the anode voltage (surge voltage) is large and vibration appears both in the anode current and in the anode voltage. On the other hand, in the present embodiment, the peak value of the reverse anode current is small, so that the peak value of the anode voltage is small and nearly no vibration occurs. In the present embodiment, the reason why the peak value of the reverse anode current is small is that the hole density on the anode side is reduced due to the application of the positive voltage to the gate electrode. The peak values of the anode current and the anode voltage are reduced, so that the noise is reduced during recovery. For this reason, it is possible to prevent malfunctions of the power conversion device using the semiconductor device of the present embodiment, as well as the electronic equipment. Further, it is not required to have any noise shielding parts, so that it is possible to reduce the size of the power conversion device and the electronic equipment.

Note that it is well known that in the insulated gate type power device, the electrical properties are degraded as the number of times of switching increases. The cause of the degradation of the electrical properties is due to charge (hole) injected into the gate insulating film from the p type body layer during switching. In contrast, in the present embodiment, the charge (hole) is reduced during switching, so that it is possible to prevent such a degradation.

As described above, according to the present embodiment, it is possible to reduce both power loss and noise, so that it is possible to increase the efficiency and reduce the size of the semiconductor device and the power conversion device using the same. Further, in the present embodiment, the degradation of the electrical properties is prevented, so that the reliability of the semiconductor device and the power conversion device using the same is increased.

Next, the sheet carrier of the p− type channel layer 3 will be described. The sheet carrier is the numerical value obtained by integrating the impurity concentration from the lower end of the gate insulating film 9 to the lower end of the p− type channel layer 3 (corresponding to “a” in FIG. 1) in the depth direction. In order to maintain the breakdown voltage with the positive voltage applied to the gate electrode 8, it is necessary to prevent the depletion layer, which extends from the pn junction between the p− type channel layer 3 and the n− type drift layer 1 to the inside of the p− type channel layer 3, from reaching the gate insulating film 9. For this reason, the lower limit of the sheet carrier of the p− type channel layer 3 is preferably 1.5×10¹⁰ cm⁻².

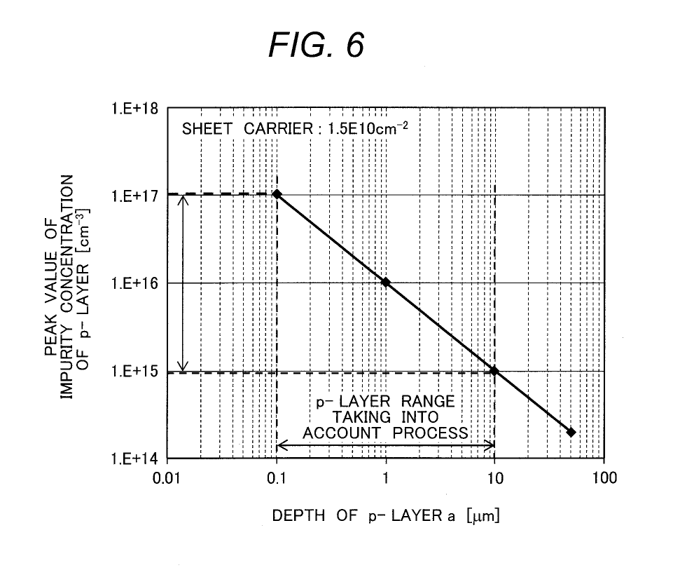

FIG. 6 shows the relationship between the depth a of the p− type channel layer 3 and the peak value of the impurity density when the sheet carrier of the p − type channel layer 3 is set to 1.5×10¹⁰ cm⁻². Note that the impurity distribution of the p− type channel layer 3 is a box profile. When the sheet carrier is constant, namely, when the product of the depth a and the impurity concentration is constant, the impurity concentration becomes small when the depth a of the p− type channel layer 3 is large, while the impurity concentration becomes large when the depth a of the p− type channel layer 3 is small.

In view of the fluctuations of the depth of the p− type channel layer 3 and the impurity concentration in the production process (ion implantation or the like), the lower limit of the depth of the p− type channel layer 3 is about 0.1 μm. On the other hand, the upper limit of the depth of the p− type channel layer 3 is about 10 μm. This is because the diffusion layer, which is the deepest layer in the production process, is a p type layer (about 10 μm deep) in the vicinity of the chip that maintains the breakdown voltage. Thus, a diffusion process is performed at a high temperature for a long time form a diffusion layer of 10 or more.

As described above, the depth a of the p− type channel layer 3 is 0.1 μm or more and 10 μm or less. The corresponding range of the peak value of the impurity concentration of the p− type channel layer 3 is 1.5×10¹⁵ cm⁻³ or more and 1.5×10¹⁷ cm⁻³ or less. Given the production variations in this concentration range, it is desirable that the depth of the p− type channel layer 3 is set to about 1 μm and the peak value of the impurity concentration of the p− type channel layer 3 is set to about 1×10¹⁶ cm⁻³.

Here, a description will be made of the consistency of the value range of the sheet carrier and impurity concentration of the p− type channel layer 3, namely, the fact that the value range of the sheet carrier and impurity concentration of the p− type channel layer 3 is constant with respect to different breakdown voltages.

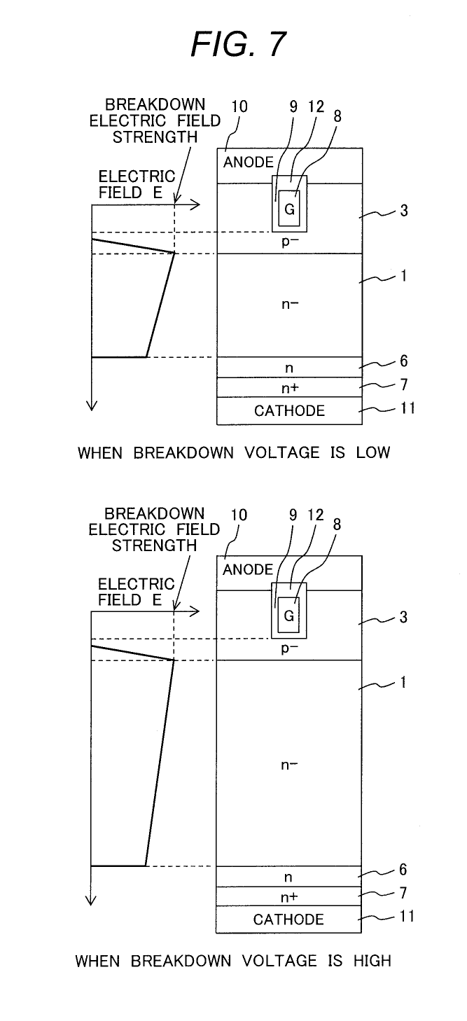

FIG. 7 shows the electric field distributions in the depth direction for the two cases. when the breakdown voltage is low, namely, when the n− type drift layer 1 is thin and the impurity concentration is high, and when the breakdown voltage is high, namely, when the n− type drift layer 1 is thick and the impurity concentration is low. The electric field distribution of the n− type drift layer 1 changes due to the variation of the breakdown voltage, however, the electric field distribution of the p− type channel layer 3 is constant.

Here, the breakdown electric field strength in the electric field distribution is the critical value of the electric field when the semiconductor device may not block the voltage (break down), which is the physical property value determined by the semiconductor material. The breakdown voltage is the voltage at which the electric field strength in the junction part between the p− type channel layer 3 and the n− type drift layer 1 reaches the breakdown electric field strength. The breakdown voltage depends on the electric field distribution in the p− type channel layer 3 and the n− type drift layer 1. As described above, the electric field distribution of the n− type drift layer changes due to the variation of the breakdown voltage, but the electric field distribution of the p− type channel layer 3 is constant, so that the electric field distribution mainly depends on the impurity concentration and thickness of the n− type drift layer 1. In other words, the magnitude of the breakdown voltage mainly depends on the n− type drift layer 1 and does not affect the p− type channel layer 3. Thus, the value range of the sheet carrier and impurity concentration of the p− type channel layer 3 is constant without depending on the breakdown voltage.

Next, the gate drive sequence according to the present embodiment will be described.

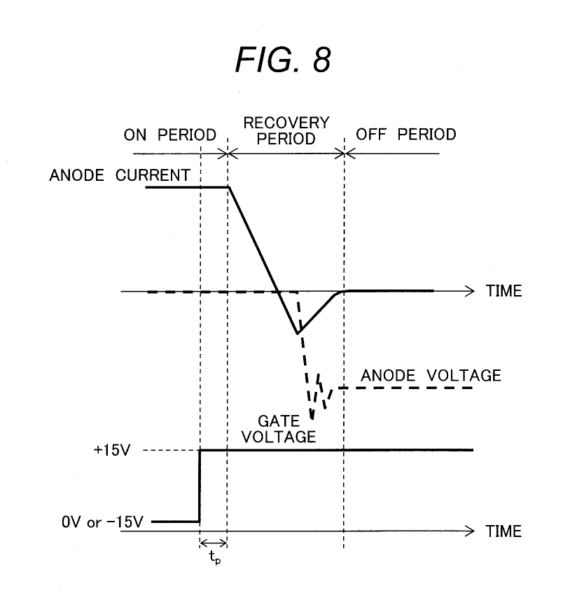

FIG. 8 shows the gate drive sequence during recovery according to the present embodiment. The upper part shows the waveforms of the anode current and the anode voltage during recovery of the diode of the present embodiment. Then, the lower part shows the waveform of the gate voltage. The positive voltage is applied to the gate electrode immediately before the anode current is reduced. In this way, the hole density is reduced and thus the recovery loss is reduced.

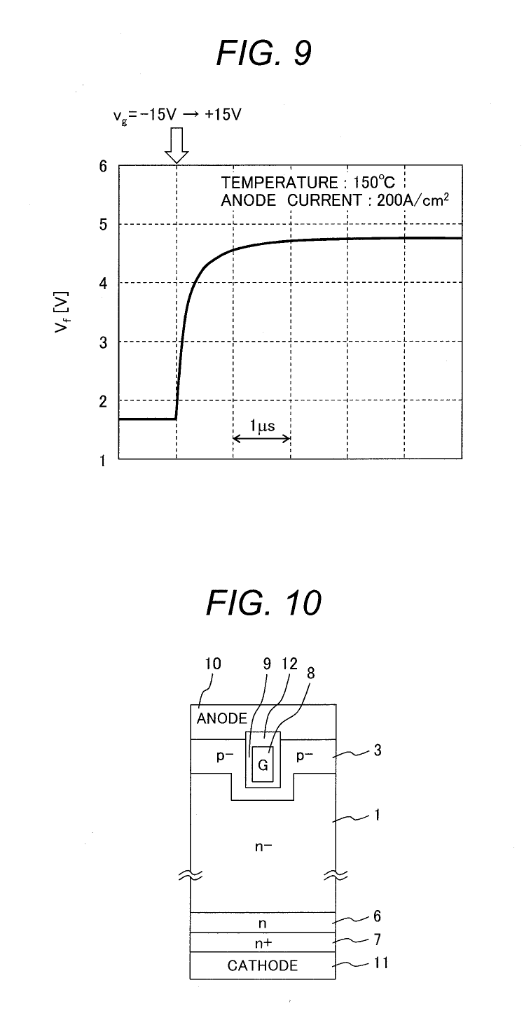

FIG. 9 shows the waveform of the forward voltage drop (Vf) before and after switching the gate voltage Vg from −15 V to +15 V. The time when Vf changes from a low state to a high state is about 2 μs. This is because it takes time until the gate voltage Vg is reflected in the total amount of holes in the n− type drift layer 1 after switching the gate voltage Vg to +15 V. Note that FIG. 9 shows the state under the condition that the breakdown voltage is 1200 V, so that the transition time until Vf is stable increases when the breakdown voltage is higher than 1200 V (when the n− type drift layer 1 is thick). However, the holes move by diffusion and drift to and through the n− type drift layer 1, so that the transition time is in the order of several μs.

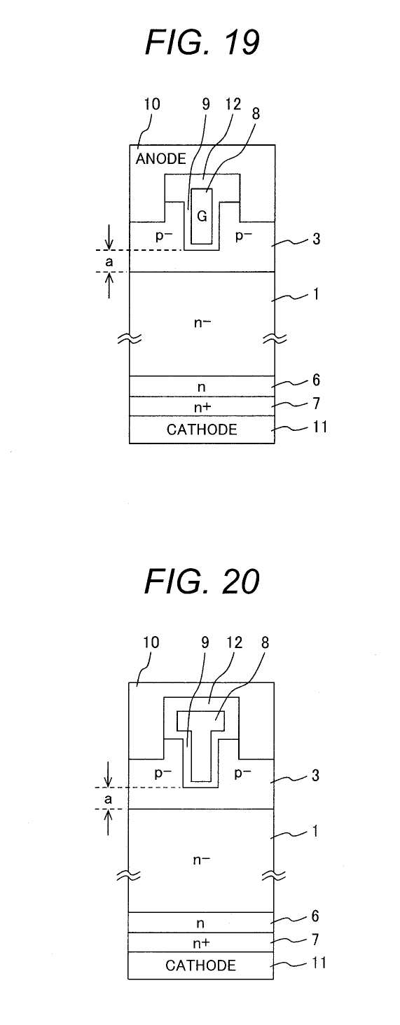

Next, variations of the first embodiment will be described with reference to FIGS. 18 to 20. The variation shown in FIG. 18 is different from the embodiment shown in FIG. 1 in that the upper end of the gate electrode 8 is located above the upper surface of the p− type channel layer 3. Further, the variation shown in FIG. 19 is different from the embodiment shown in FIG. 1 in that the upper end of the gate electrode 8 is located above the upper surface of the p− type channel layer 3 and that the anode electrode 10 is brought into contact with the p− type channel layer 3 within a concave portion 13 provided in the upper surface of the p− type channel layer 3. Further, the variation shown in FIG. 20 is different from the embodiment shown in FIG. 1 in that the upper part of the gate electrode 8 extends in the lateral direction over the upper surface of the p− type channel layer 3, and thus has what is called T shape. Note that also in the variation shown in FIG. 20, similarly to the variation shown in FIG. 19, the anode electrode 10 is brought into contact with the p− type channel layer 3 within the concave portion 13.

According to the embodiment described above, it is possible to reduce the loss and noise, so that it is possible to increase the efficiency and reduce the size and cost of the semiconductor device and the power conversion device using the same.

### Second Embodiment

FIG. 10 is a cross-sectional view of an insulated gate type vertical semiconductor device which is a second embodiment of the present invention. Also this embodiment is a trench gate control diode. The present embodiment is different from the first embodiment in that the depth from the upper surface of the p− type channel layer 3 to the junction part between the p− type channel layer 3 and the n− type drift layer 1 is deep in the lower part of the gate electrode 8, and is shallower on both sides of the lower part of the gate electrode 8 in the lateral direction than in the lower part of the gate electrode 8. In this way, the p− type channel layer 3 is formed deep in the lower part of the gate electrode 8, so that the depletion layer, which extends from the junction between the n− type drift layer 1 and the p− type channel layer 3 to the inside of the p− type channel layer 3, is prevented from reaching the n type inversion layer that is formed in the surface of the p− type channel layer 3 when the positive voltage is applied to the gate electrode 8. In this way, it is possible to reduce the recovery loss without reducing the breakdown voltage.

Note that also in the present embodiment, it is possible to reduce the recovery loss by setting the gate voltage to a positive voltage lower than the threshold value to reduce the potential with respect to the electrons.

Similarly to the first embodiment, according to the second embodiment, it is possible to reduce both the loss and noise, so that it is possible to increase the efficiency and reduce the size and cost of the semiconductor device and the power conversion device using the same.

### Third Embodiment

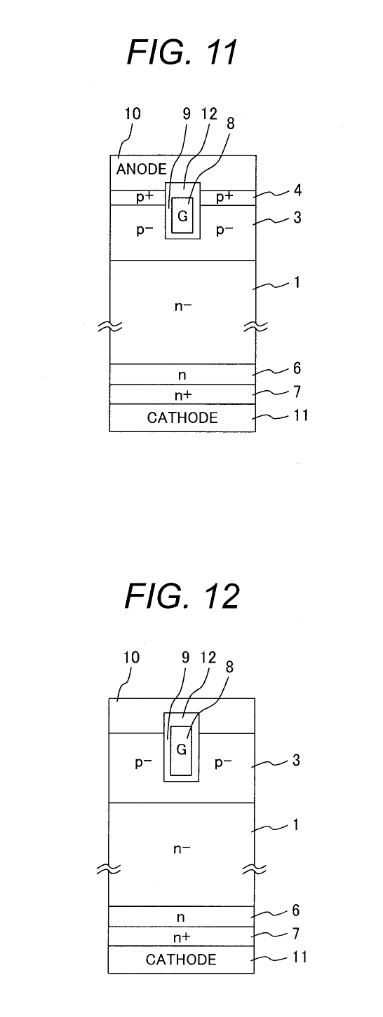

FIG. 11 is a cross-sectional view of an insulated gate type vertical semiconductor device which is a third embodiment of the present invention. Also this embodiment is a trench gate control diode. The present embodiment is different from the first embodiment in that a p+ layer 4 whose impurity concentration is higher than the p− type channel layer 3 is provided in the upper surface of the p− type channel layer 3. The use of the p+ layer 4 can reduce the contact resistance between the anode electrode 10 and the p− type channel layer 3. Note that according to the studies of the present inventors, the peak value of the impurity concentration of the p+ layer 4 is preferably 1×10¹⁸ cm⁻³ or more and 1×10²⁰ cm⁻³ or less, in order to reduce the contact resistance while preventing the increase in the recovery loss. Further, the depth of the p+ layer 4 is preferably 100 nm or less in terms of the reduction in the recovery loss.

Also with this embodiment, it is possible to reduce both the loss and noise, so that it is possible to increase the efficiency reduce the size and cost of the semiconductor device and the power conversion device using the same.

### Fourth Embodiment

FIG. 12 is a cross-sectional view of an insulated gate type vertical semiconductor device which is a fourth embodiment of the present invention. Also this embodiment is a trench gate control diode. The present embodiment is different from the first embodiment in that the gate electrode 8 is provided over the surfaces of the p− type channel layer 3, the contact part of the anode electrode 10 and the p− type channel layer 3, and the anode electrode 10, respectively, through the gate insulating film 9 in the depth direction of the trench groove. Because of this gate structure, the application of the positive voltage to the gate electrode 8 can reduce the Schottky barrier at the interface between the anode electrode 10 and the p− type channel layer 3. In this way, the electrons injected from the n+ type cathode layer 7 are likely to be discharged to the anode electrode 10. As a result, the recovery loss is reduced. During conduction, the Schottky barrier is increased and the barrier against the holes is lowered by the application of the negative voltage to the gate electrode 8. As a result, the hole injection is promoted and thus the forward voltage Vf can be reduced.

Also with this embodiment, it is possible to reduce the loss and noise, so that it is possible to increase the efficiency reduce the size and cost of the semiconductor device and the power conversion device using the same.

### Fifth Embodiment

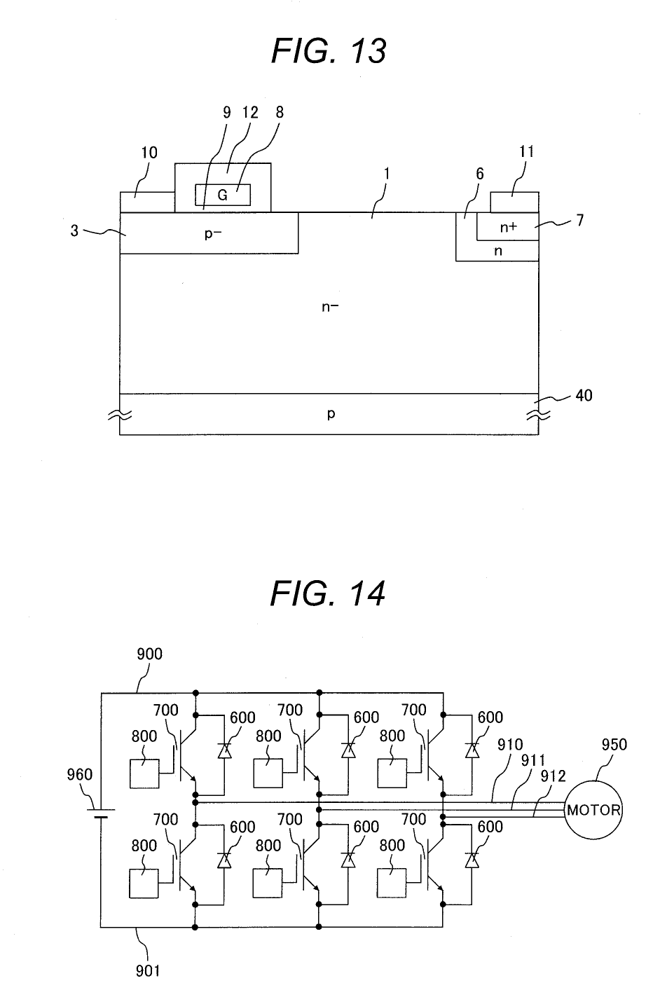

FIG. 13 is a cross-sectional view of an insulated gate type lateral semiconductor device which is a fifth embodiment of the present invention. The present embodiment is different from the first embodiment in that the insulated gate including the gate electrode 8 and the gate insulating film 9, the anode electrode 10, and the cathode electrode 11 are all provided over one surface of the n− type drift layer 1. In the present embodiment, of the end portions in the insulating gate, the end portion on the side of the junction part between the n− type drift layer 1 and the p− type channel layer 3 is located within the surface of the p− type channel layer 3, and at the same time, is located at a position distant from the junction part between the n− type drift layer 1 and the p− type channel layer 3.

Note that the production process of the lateral semiconductor device is close to the production process of IC (Integrated Circuits), so that the lateral semiconductor device is easy to be mounted to the IC.

Similarly to the first embodiment, also with this embodiment, it is possible to reduce power loss and noise, so that it is possible to increase the efficiency and reduce the size and cost of the semiconductor device and the power conversion device using the same.

### Sixth Embodiment

Next, a drive device for driving semiconductor circuits using the semiconductor devices according to the first to fifth embodiments will be described.

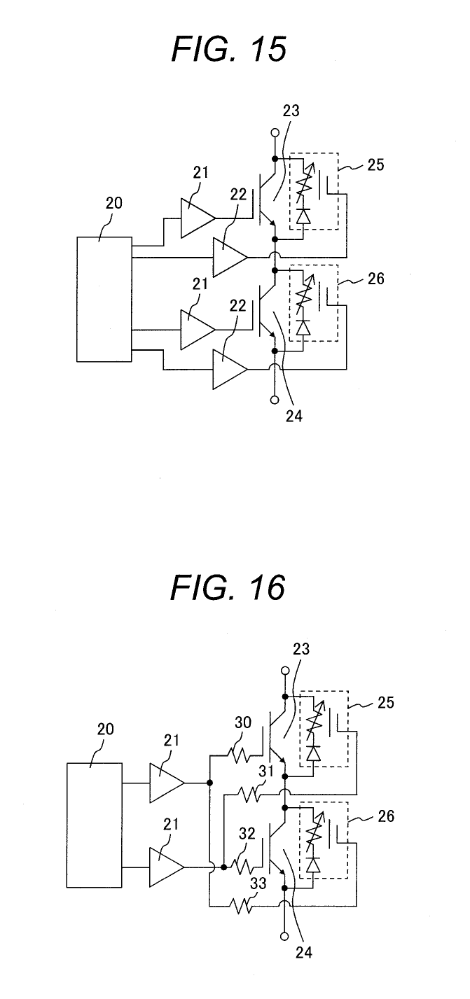

FIG. 15 shows a drive device of a semiconductor circuit, which is a sixth embodiment of the present invention. The present embodiment includes: a control circuit 20; two drive circuits 21 for driving an upper arm IGBT 23 and a lower arm IGBT 24 in response to an IGBT instruction signal from the control circuit 20; and two drive circuits 22 for driving an upper arm insulated gate control diode 25 and a lower arm insulated gate control diode 26 in response to a diode instruction signal from the control circuit 20. Here, any of the first to fifth embodiments described above is used as the insulated gate control diodes 25 and 26. Note that the circuit symbol of each of the insulated gate control diodes 25 and 26 in the figure shows that the resistance value of the diode is controlled by the gate electrode. However, this symbol is not commonly used and is generated by the inventors.

As described in FIG. 8, in the insulated gate control diode which is an embodiment of the present invention, the positive voltage is applied to the gate electrode immediately before the anode current starts to drop, namely, immediately before recovery, in order to reduce the recovery loss. Here, the recovery of the diode is a phenomenon associated with turn-on of the IGBT of the opposite arm to the arm of the diode. Thus, in the drive circuit according to the present embodiment, the control circuit 20 generates the IGBT instruction signal and the diode instruction signal so that the timing when the IGBT is turned on is synchronized with the timing when the positive voltage is applied to the gate electrode of the insulated gate control diode of the opposite arm to the particular IGBT. In this way, it is possible to apply the positive voltage to the gate electrode immediately before recovery.

According to the present embodiment, similarly to the other embodiments, it is possible to increase the efficiency and reduce the size of the semiconductor device and the power conversion device using the same.

### Seventh Embodiment

FIG. 16 shows a drive device of a semiconductor circuit, which is a seventh embodiment of the present invention. The present embodiment is different from the sixth embodiment in that the number of outputs of the control circuit 20 is reduced from 4 to 2. More specifically, one of the two outputs of the control circuit 20 is coupled to the drive circuit for driving the upper arm IGBT 23 and to the drive circuit for driving the lower arm insulated gate control diode 26. Then, the other is coupled to the drive circuit for driving the upper arm insulated gate control diode 25 and to the lower arm IGBT 24. A gate resistance 30 of the upper arm IGBT 23 is set greater than a gate resistance 33 of the lower arm insulated gate control diode 26. In this way, it is possible to turn on the IGBT 23 after the positive voltage is applied to the gate electrode of the insulated gate control diode 26. In other words, it is possible to apply the positive voltage to the gate of the insulated gate control diode immediately before recovery. Similarly, by setting a gate resistance 32 of the lower arm IGBT 24 greater than the gate resistance 33 of the upper arm insulated gate control diode 25, it is possible to turn on the IGBT 24 after the positive voltage is applied to the gate electrode of the diode 25. In other words, it is possible to apply the positive voltage to the gate of the insulated gate control diode immediately before recovery.

According to the present embodiment, it is possible to reduce the size of the drive device, thereby achieving a reduction in size of the power conversion device, in addition to the same effects as those of the other embodiments.

### Eighth Embodiment

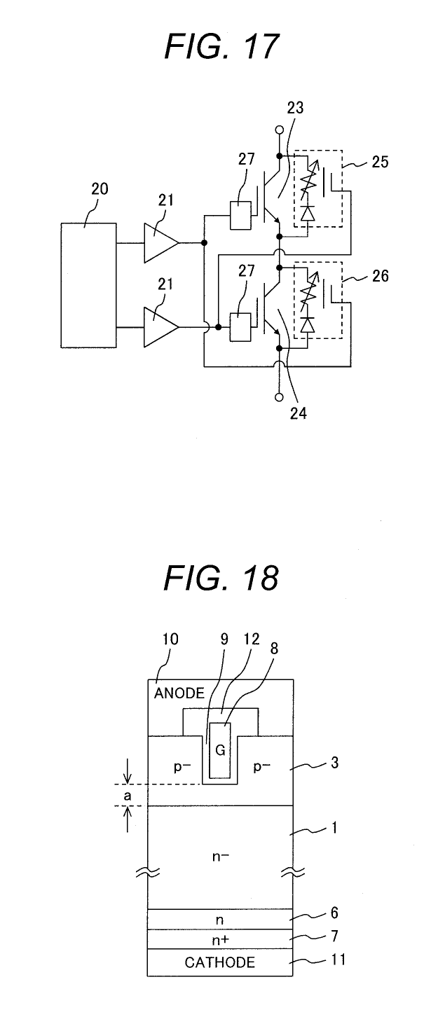

FIG. 17 shows a drive device of a semiconductor circuit, which is an eighth embodiment of the present invention. The present embodiment is different from the seventh embodiment in that delay circuits 27 are provided in each of the drive circuits of the upper arm IGBT 23 and the lower arm IGBT 24, in place of the gate resistances 31 to 34 in FIG. 16. In other words, the delay circuits 27 are respectively coupled between the drive circuit for driving the upper arm IGBT 23 as well as the lower arm insulated gate control 26, and the gate of the upper arm IGBT 23, and between the drive circuit for driving the lower arm IGBT 24 as well as the upper arm insulated gate control 25, and the gate of the lower arm IGBT 24. In this way, similarly to the seventh embodiment, it is possible to turn on the IGBT after the positive voltage is applied to the gate of the insulated gate control diode. In other words, it is possible to apply the positive voltage to the gate of the insulated gate control diode immediately before recovery.

According to the present embodiment, in addition to the same effects as those of the other embodiments, it is possible to reduce the size of the drive circuit, so that it is possible to reduce the size of the power conversion device.

### Ninth Embodiment

A power conversion device which is a ninth embodiment of the present invention will be described with reference to FIG. 14.

The present embodiment is a three-phase inverter device, in which the insulated gate control diodes and drive circuits described in the above embodiments are respectively used as the diode 600 and the gate drive circuit. Note that the circuit symbol of a common diode is used for the insulated gate control diode in FIG. 14 for convenience. Further, the gate drive circuit 800 is shown by a simple block diagram and the detailed circuit configuration as shown in FIGS. 15 to 17 is not shown here.

The present embodiment includes a pair of DC terminals 900 and 901, and AC terminals for the same number of AC phases, namely, three AC terminals 910, 911, and 912. An IGBT 700 is coupled between each of the DC terminals and each of the AC terminals, which is used as one semiconductor switching element. Thus, the three-phase inverter device as a whole includes six IGBTs. Further, the diode 600 is connected in reverse parallel to each IGBT. Note that the number of IGBTs 700 and diodes 600 is set to an appropriate number according to the number of AC phases, the power capacity of the power conversion device, and the breakdown voltage and current capacity of a single unit of the semiconductor switching element 700.

Each IGBT 700 and each diode 600 are driven by the gate drive circuit 800. In this way, the DC power received by the DC terminals 900 and 901 from the DC power supply 960 is converted to AC power. Then, the AC power is output from the AC terminals 910, 911, and 912. Each AC output terminal is coupled to a motor 950 such as an induction machine or a synchronous machine. In this way, the motor 950 is rotated and driven by the AC power output from each of the AC terminals.

According to the present embodiment, the insulated gate control diodes of the first to fifth embodiments are used as the diode 600, and the drive circuits of the sixth to eighth embodiments are also used. In this way, it is possible to reduce the power loss of the diode and to reduce the loss and size of the inverter device.

Although the present embodiment is an inverter device, the semiconductor device and the drive circuit according to the present invention can also be applied to other power conversion devices such as a converter and a chopper, which the same effect can be obtained.

It should be understood that the present invention is not limited to the above embodiments and various changes and modifications can be made within the scope of the technical idea of the present invention. For example, in the above embodiments, the conductivity type of each semiconductor layer may be reversed. Further, the semiconductor material configuring the semiconductor device is not limited to silicon as used in the above embodiments and may be wide-gap materials such as SiC (silicon carbide) and GaN (gallium nitride).

### REFERENCE SINGS LIST

1: n− type drift layer

3: p− type channel layer

4: p+ type anode layer

6: n type buffer layer

7: n+ type cathode layer

8: gate electrode

9: gate insulating film

10: anode electrode

11: cathode electrode

12: insulating film

13: concave portion

20: control circuit

21: drive circuit of IGBT

22: drive circuit of diode

23: upper arm IGBT

24: lower arm IGBT

25: upper arm diode

26: lower arm diode

27: delay circuit

30, 31, 32, 33: gate resistance

600: flywheel diode

700: IGBT

800: gate circuit

900, 901: DC terminal

910, 911, 912: AC

950: motor

960: DC power supply

1. A semiconductor device comprising:
a first semiconductor layer of a first conductivity type;
a second semiconductor layer of the first conductivity type, which is adjacent to the first semiconductor layer and has an impurity concentration lower than the first semiconductor layer;
a third semiconductor layer of a second conductivity type adjacent to the second semiconductor layer;
a first electrode electrically coupled to the third semiconductor layer;
a second electrode brought into contact with the first semiconductor layer; and
an insulated gate provided over the surface of the third semiconductor layer,
wherein the end portion of the insulated gate is located at a position distance from the junction part between the second semiconductor layer and the third semiconductor layer within the surface of the semiconductor layer.

2. A semiconductor device according to claim 1,
wherein the insulated gate is a trench gate,
wherein the depth from the upper surface of the third semiconductor layer to the junction between the third semiconductor layer and the second semiconductor layer is deeper in the lower part of the trench gate than the depth on both sides of the lower part of the trench gate in the lateral direction.

3. A semiconductor device according to claim 1,
wherein a fourth semiconductor layer of the second conductivity type having an impurity concentration higher than the third semiconductor layer is provided in the surface of the third semiconductor layer,
wherein the first electrode is brought into contact with the fourth semiconductor layer.

4. A semiconductor device according to claim 1,
wherein the insulated gate is a trench gate,
wherein a gate electrode is provided over the surfaces of the third semiconductor layer, the contact part of the first electrode and the third semiconductor layer, and the first electrode, respectively, along the depth direction of the trench groove.

5. A semiconductor device according to claim 1,
wherein the peak value of the impurity concentration of the third semiconductor layer is 1.5×10¹⁵ cm⁻³ or more and 1.5×10¹⁷ cm⁻³ or less.

6. A semiconductor device according to claim 1,
wherein the depth of the third semiconductor layer is 0.1 μm or more and 10 μm or less.

7. A semiconductor device according to claim 1,
wherein the first electrode, the second electrode, and the insulated gate are located in the same surface of the second semiconductor layer.

8. A semiconductor device according to claim 1,
wherein a negative voltage is applied to the insulated gate in a conductive state.

9. A semiconductor device according to claim 1,
wherein a positive voltage is applied to the insulated gate before moving from a conductive state to a non-conductive state.

10. A semiconductor device according to claim 9,
wherein the difference between the time point when the current of the semiconductor device is reduced and the time point when the positive voltage is applied to the insulated gate is 2 μs or more.

11. A drive device of a semiconductor circuit having an upper arm and a lower arm, each including a parallel circuit of a semiconductor switching element and a diode, in which a semiconductor device according to claim 1 is used as the diode,
wherein the drive device includes:
a plurality of drive circuits coupled to each of the semiconductor switching elements and each of the diodes; and
a control circuit for generating an instruction signal given to the plurality of drive circuits.

12. A drive device of a semiconductor circuit having an upper arm and a lower arm, each including a parallel circuit of a semiconductor switching device and a diode, in which a semiconductor device according to claim 1 is used as the diode,
wherein the drive device includes:
a first drive circuit for driving the semiconductor switching element of the upper arm as well as the diode of the lower arm;
a second drive circuit for driving the semiconductor switching element of the lower arm as well as the diode of the upper arm; and
a control circuit for generating an instruction signal given to the first and second drive circuits,
wherein the resistance value of a first gate resistance coupled between the gate of the semiconductor switching element of the upper arm and the first drive circuit is greater than the resistance value of a second gate resistance coupled between the gate of the diode of the lower arm and the first drive circuit,
wherein the resistance value of a third gate resistance coupled between the gate of the semiconductor switching element of the lower arm and the second drive circuit is greater than the resistance value of a fourth gate resistance coupled between the gate of the diode of the upper arm and the second drive circuit.

13. A drive device of a semiconductor circuit having an upper arm and a lower arm, each including a semiconductor switching element and a diode, in which a semiconductor device according to claim 1 is used as the diode,
wherein the drive device includes:
a first drive circuit for driving the semiconductor switching element of the upper arm as well as the diode of the lower arm;
a second drive circuit for driving the semiconductor switching element of the lower arm as well as the diode of the upper arm; and
a control circuit for generating an instruction signal given to the first and second drive circuits,
wherein the drive device includes:
a first delay circuit coupled between the gate of the semiconductor switching element of the upper arm and the first drive circuit; and
a second delay circuit coupled between the gate of the semiconductor switching element of the lower arm and the second drive circuit.

14. A power conversion device comprising:
a pair of DC terminals;
the same number of AC terminals as the number of AC phases;
a plurality of semiconductor switching elements provided between the DC terminals and the AC terminals; and
a plurality of diodes connected in reverse parallel to the semiconductor switching elements,
wherein the diode is a semiconductor device according to claim 1.
